(19) United States
(12) Patent Application Publication
(10) Pub. No.: US 2024/0372047 A1
(43) Pub. Date: Nov. 7, 2024

(54) DISPLAY DEVICE

(71) Applicant: LG ELECTRONICS INC., Seoul (KR)

(72) Inventors: Naree KIM, Seoul (KR); Kiseok KIM, Seoul (KR); Dongkyu LEE, Seoul (KR); Jeongsik CHOI, Seoul (KR); Sangtae PARK, Seoul (KR)

(73) Assignee: LG ELECTRONICS INC., Seoul (KR)

(21) Appl. No.: 18/285,792

(22) PCT Filed: Apr. 6, 2021
(86) PCT No.: PCT/KR2021/004290

§ 371 Date: Oct. 5, 2023

(51) Int. Cl. H01L 33/58; G09F 9/302; H01L 25/075; H01L 27/15; H01L 33/62

(52) U.S. Cl. CPC H01L 33/58; H01L 25/0753; H01L 27/156; H01L 33/62; G09F 9/3026

(57) ABSTRACT

Disclosed is a display device. The display device may include: a display panel; and a module cover to which the display panel is coupled, wherein the display panel may include: a flat substrate; a plurality of electrode pads formed on the substrate; a plurality of light emitting elements mounted on each of the plurality of electrode pads; an optical layer covering the plurality of light emitting elements, and formed on the substrate; and a plurality of fillers formed of a spherical particle, and distributed inside the optical layer, wherein 75 to 80 percent of the plurality of fillers may have a diameter of 2 to 16 micrometers, and a weight ratio of the plurality of fillers compared to the optical layer may be 15 to 23 percent.

### TECHNICAL FIELD

The present disclosure relates to a display device.

### BACKGROUND ART

As information society develops, the demand for display devices is also increasing in various forms. In response to this, various display devices such as Liquid Crystal Display Device (LCD), Plasma Display Panel (PDP), Electroluminescent Display (ELD), Vacuum Fluorescent Display (VFD), Organic Light Emitting Diode (OLED), and Micro Light Emitting Diode (Micro LED) have been researched and used in recent years.

Digital Signage is a display device that provides not only broadcast programs but also specific information in public places such as airports, hotels, hospitals, and subway stations as a communication tool that can induce marketing, advertising, and training effects for companies, and customer experience, as well as general TV.

Digital signage is a medium that expresses various contents and commercial advertisements by installing display panels such as Liquid Crystal Display (LCD), Plasma Display Panel (PDP), Organic Light Emitting Diode (OLED), and Micro Light Emitting Diode (LED) on devices such as outdoor locations or street furniture, and may be installed not only in homes but also in the public movement lines such as apartment elevators, subway stations, subway trains, buses, universities, banks, convenience stores, discount stores, and shopping malls.

Recently, as digital signage has become larger and larger, much research has been conducted to improve the image quality of display panels.

### DISCLOSURE OF INVENTION

### Technical Problem

An object of the present disclosure is to solve the foregoing and other problems.

An object of the present disclosure may be to provide a display device that improves a color difference in a display panel.

An object of the present disclosure may be to provide a display device that improves the light extraction efficiency of a display panel.

An object of the present disclosure may be to provide a display device that improves the image quality of a display panel.

### Solution to Problem

According to an aspect of the present disclosure, a display device may include: a display panel; and a module cover to which the display panel is coupled, wherein the display panel may include: a flat substrate; a plurality of electrode pads formed on the substrate; a plurality of light emitting elements mounted on each of the plurality of electrode pads; an optical layer covering the plurality of light emitting elements, and is formed on the substrate; and a plurality of fillers formed of a spherical particle, and distributed inside the optical layer, wherein 75 to 80 percent of the plurality of fillers may have a diameter of 2 to 16 micrometers, and a weight ratio of the plurality of fillers compared to the optical layer may be 15 to 23 percent.

### Advantageous Effects of Invention

According to at least one embodiment of the present disclosure, a display device that improves a color difference in a display panel can be provided.

According to at least one embodiment of the present disclosure, a display device that improves the light extraction efficiency of a display panel can be provided.

According to at least one embodiment of the present disclosure, a display device that improves the image quality of a display panel can be provided.

Further scope of applicability of the present disclosure will become apparent from the following detailed description. However, it should be understood that the detailed description and specific embodiments such as preferred embodiments of the present disclosure are given by way of illustration only, since various changes and modifications within the spirit and scope of the present disclosure may be clearly understood by those skilled in the art.

### BRIEF DESCRIPTION OF DRAWINGS

FIGS. 1 to 4 are diagrams showing examples of display device according to embodiments of the present disclosure.

FIGS. 5 and 6 are diagrams showing an example of light extraction efficiency according to the particle size distribution and content of filler according to embodiments of the present disclosure.

FIGS. 7 and 8 are diagrams showing another example of light extraction efficiency according to the particle size distribution and content of filler according to embodiments of the present disclosure.

FIGS. 9 to 11 are diagrams showing examples of display panels according to embodiments of the present disclosure.

### MODE FOR INVENTION

Description will now be given in detail according to exemplary embodiments disclosed herein, with reference to the accompanying drawings. For the sake of brief description with reference to the drawings, the same or equivalent components may be denoted by the same reference numbers, and description thereof will not be repeated.

In general, suffixes such as “module” and “unit” may be used to refer to elements or components. Use of such suffixes herein is merely intended to facilitate description of the specification, and the suffixes do not have any special meaning or function. In the present disclosure, that which is well known to one of ordinary skill in the relevant art has generally been omitted for the sake of brevity. The accompanying drawings are used to assist in easy understanding of various technical features and it should be understood that the embodiments presented herein are not limited by the accompanying drawings. As such, the present disclosure should be construed to extend to any alterations, equivalents and substitutes in addition to those which are particularly set out in the accompanying drawings.

It will be understood that although the terms first, second, etc. may be used herein to describe various elements, these elements should not be limited by these terms. These terms are only used to distinguish one element from another.

It will be understood that when an element is referred to as being “connected with” another element, there may be intervening elements present. In contrast, it will be understood that when an element is referred to as being “directly connected with” another element, there are no intervening elements present.

A singular representation may include a plural representation unless context clearly indicates otherwise.

In the present application, it should be understood that the terms “comprises, includes,” “has,” etc. specify the presence of features, numbers, steps, operations, elements, components, or combinations thereof described in the specification, but do not preclude the presence or addition of one or more other features, numbers, steps, operations, elements, components, or combinations thereof.

Hereinafter, a display panel is described using micro LED as an example, but the display panel applicable to the present disclosure is not limited thereto.

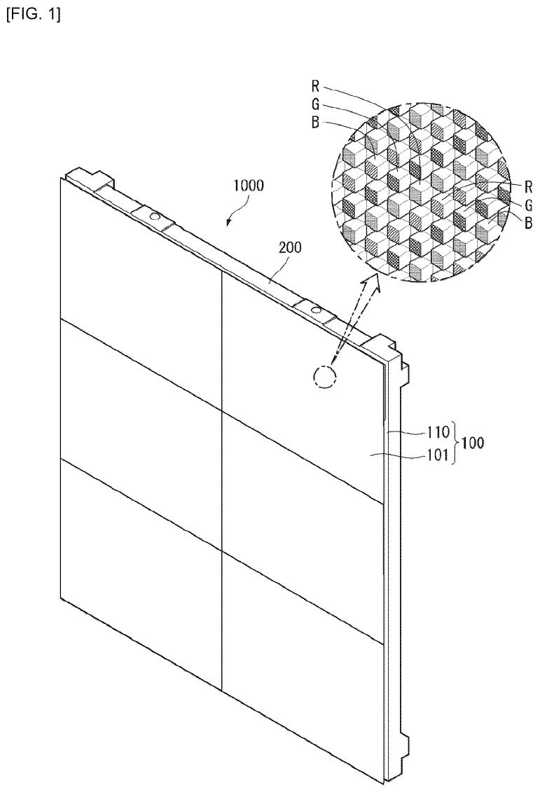

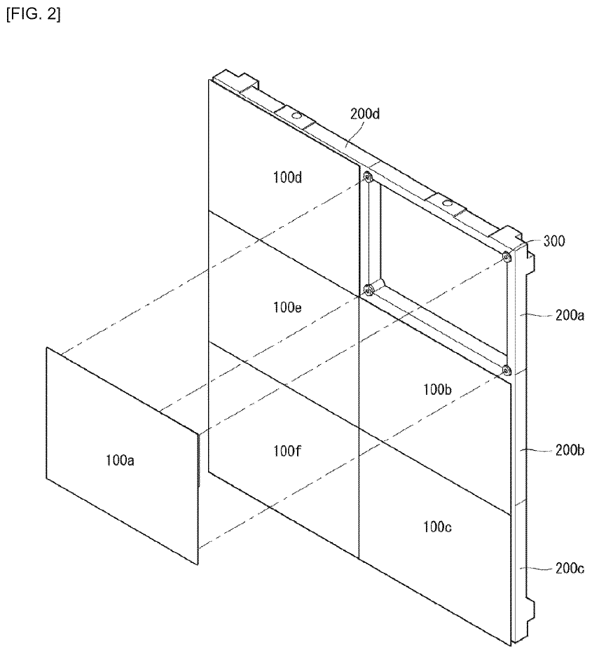

Referring to FIGS. 1 and 2, a multi-display device 1000 may include a display module 100 capable of displaying an image, a frame 200 supporting the display module 100, and a leveling unit 300 that is mounted between the display module 100 and the frame 200, and adjusts a gap between them.

The display module 100 may include a display panel 101 and a module cover 110 located in a rear of the display panel 101.

The display panel 101 may include a plurality of pixels R, G, B. A plurality of pixels R, G, B may be formed in each area where a plurality of data lines and a plurality of gate lines intersect. A plurality of pixels R, G, B may be disposed or arranged in a matrix form.

For example, a plurality of pixels R, G, B may include a red (hereinafter, R) subpixel, a green (hereinafter, ‘G’) subpixel, and a blue (hereinafter, ‘B’) subpixel. A plurality of pixels R, G, B may further include a white (hereinafter, ‘W’) subpixel.

The side of the display panel 101 that displays images may be referred to as a front or a front surface. When the display panel 101 displays an image, the side from which the image cannot be observed may be referred to as a rear or a rear surface. When looking at the display panel 101 from the front or the front surface, the upper portion may be referred to as an upper side or an upper surface. Likewise, the lower portion may be referred to as a lower side or a lower surface. Likewise, the right portion may be referred to as a right side or a right surface, and the left portion referred to as a left side or a left surface.

The module cover 110 is disposed in the rear of the display panel 101 so that the display panel 101 can be coupled thereto.

The display module 100 may include a first display module 100a to a sixth display module 100f. The first display modules 100a to the sixth display module 100f may be arranged adjacent to each other in the up-down or left-right direction.

For example, a first display module 100a may be disposed in the upper right side of the frame 200. A second display module 100b may be disposed in the lower side of the first display module 100a. A third display module 100c may be disposed in the lower side of the second display module 100b. A fourth display module 100d may be disposed in the left side of the first display module 100a. A fifth display module 100e may be disposed in the lower side of the fourth display module 100d and in the left side of the second display module 100b. A sixth display module 100f may be disposed in the lower side of the fifth display module 100e and in the left side of the third display module 100c.

The frame 200 may be disposed in the rear of the plurality of display modules 100. The front surface of the frame 200 may face the rear of the display module 100. The frame 200 may be disposed to correspond to the display module 100 in the thickness direction or front-rear direction of the display module 100. The frame 200 may be formed in the shape of a picture frame with an open central area. The frame 200 may be formed to be long in the up-down and left-right directions so that a plurality of display modules 100 are mounted. For example, the length of the upper side of the frame 200 may be substantially equal to a sum of the lengths of the upper side of the first display module 100a and the upper side of the fourth display module 100d. In addition, the length of the right side of the frame 200 may be substantially equal to a sum of the lengths of the right side of the first display module 100a, the right side of the second display module 100b, and the right side of the third display module 100c. However, it is not limited thereto. The frame 200 may be formed to be longer or shorter than the display module 100 depending on the external environment such as the building or wall in which it is installed.

The frame 200 may have a thickness greater than that of the plurality of display modules 100.

FIGS. 1 and 2 illustrate that it is formed as one frame 200, but it is not limited thereto. The frame 200 may include a first frame 200a to a sixth frame 200f. For example, the first frames 200a to 6th frames 200f may be stacked or assembled in substantially the same manner as the above-described first display module 100a to sixth display module 100f. Accordingly, a n-th display module 100 may be mounted on a n-th frame 200. Here, n may be a natural number.

The leveling unit 300 may be disposed between the plurality of display modules 100 and the plurality of frames 200. The leveling unit 300 may be mounted on the frame 200 in the thickness direction of the display module 100. The leveling unit 300 mounted on the front surface of the frame 200 may be attached to the rear surface of the display module 100. The leveling unit 300 may adjust a separation distance between the rear surface of the display module 100 and the front surface of the frame 200. There may be a plurality of leveling units 300. The leveling unit 300 may be disposed in each corner of the frame 200. The leveling unit 300 may be disposed in the display module 100 and in each corner of the frame 200 to adjust the separation distance between them.

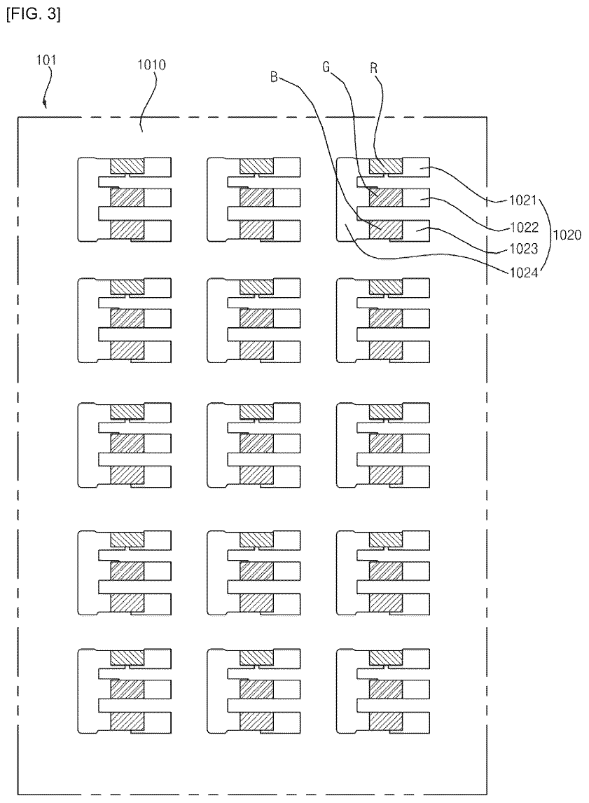

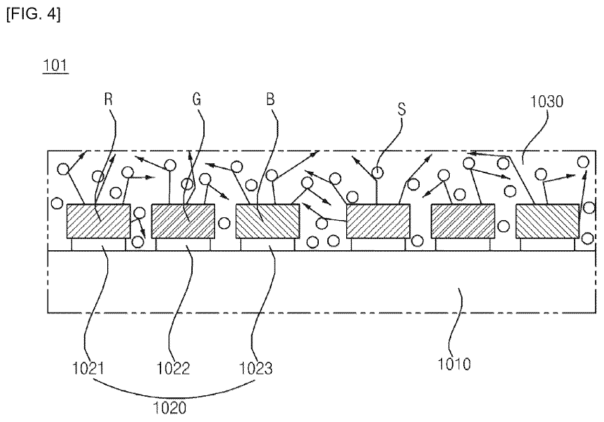

Referring to FIGS. 3 and 4, the display panel 101 may include a substrate 1010, electrode pads 1020, and light emitting elements RGB. For example, the substrate 1010 may be a flat PCB. The electrode pad 1020 may be formed on the substrate 1010. There may be a plurality of electrode pads 1020. The electrode pad 1020 may be formed of a conductive metal. The electrode pad 1020 may form a certain pattern on the substrate 1010. For example, the electrode pad 1020 may have a W shape. The electrode pad 1020 may include a first part 1021, a second part 1022, a third part 1023, and a connection part 1024.

The light emitting element RGB may be an LED chip. A plurality of light emitting elements RGB may be mounted on the electrode pad 1020. For example, the light emitting element RGB may be bonded on the electrode pad 1020. A first light emitting element R may be mounted on a first part 1021, a second light emitting element G may be mounted on a second part 1022, and a third light emitting element B may be mounted on a third part 1023. For example, the first light emitting element R may emit red light, the second light emitting element G may emit green light, and the third light emitting element B may emit blue light. For example, the light emitting element RGB may be an LED flip chip.

The electrode pads 1020 may be visually recognized from the front surface of the display panel 101. When the electrode pads 1020 are visually recognized and the light emitting elements RGB are not switched on, the display panel 101 may be mistaken as displaying light information in addition to a black screen, or the black color expression of the display panel 101 may be reduced.

In addition, as the light emitting element RGB is bonded to the electrode pad 1020, the light emitting element RGB may not remain horizontal or may be tilted. When the light emitting element RGB is tilted and bonded to the electrode pad 1020, the irradiation angle of the light emitting element RGB may not be constant. That is, if the light emitting element RGB is tilted on the electrode pad 1020, a representation of natural colors on the front surface of the display panel 101 may be disparate, and a user may perceive that there is a difference in the color sense. This may mean that the image quality of the display panel 101 deteriorates.

Referring to FIG. 4, an optical layer 1030 may be located on the substrate 1010 on which the light emitting element RGB is mounted. The optical layer 1030 may cover and seal the light emitting element RGB mounted on the substrate 1010. The optical layer 1030 may be coated in a liquid form on the substrate 1010 and the light emitting element RGB and cured. For example, the optical layer 1030 may include silicone. The optical layer 1030 may be transparent.

A filler S may be contained in the optical layer 1030. For example, the filler S may be a plurality of particles S. The filler S may be, for example, SiO₂. For example, the filler S may be spherical and have a diameter of 500 nanometers to 5 micron meters.

The optical layer 1030 including the filler S may be aged at about 60 degrees Celsius for about 1 hour. The thickness of the aged optical layer 1030 may be reduced through a lapping process that grinds the surface. The surface processed through the lapping process may be the upper surface of the optical layer 1030. The filler S may be exposed to the upper surface of the optical layer 1030.

For example, the thickness of the optical layer 1030 may be about 150 micrometers, and the thickness from the upper surface of the light emitting element RGB to the upper surface of the optical layer 1030 may be about 50 micrometers. The thickness of the light emitting element RGB may be about 80 micrometers, and the thickness of the electrode pad 1020 may be about 20 micrometers.

The light provided from the light emitting element RGB may be refracted or scattered in the filler S. The light scattered from the filler S may leak out of the optical layer 1030. After cured, the optical layer 1030 may be transparent. For example, the cured optical layer 1030 containing silicon may have a refractive index of 1.5 to 1.6. Accordingly, light may be totally reflected inside the optical layer 1030. The filler S may refract or scatter light that is totally reflected inside the optical layer 1030.

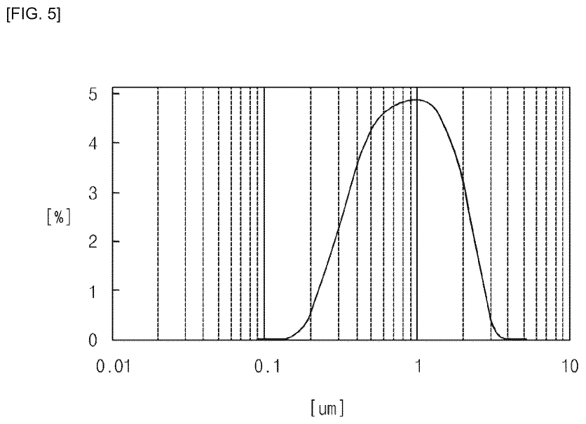

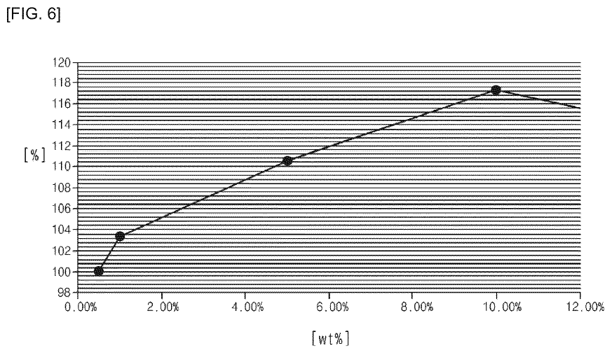

Referring to FIGS. 5 and 6, the filler S may include a plurality of fillers S of different sizes. The sizes of the fillers S may form a normal distribution. The plurality of fillers S may be 500 nanometer fillers. FIG. 5 shows the particle size distribution of fillers S, the horizontal axis may be the size (micrometer, log scale) of the fillers, and the vertical axis may be the quantity distribution (percent).

The fillers S may be contained in the optical layer 1030. For example, the weight ratio of the filler S to the optical layer 1030 may be 0.5 percent, and the light passing through the optical layer 1030 from the above-described light emitting elements RGB may be 580 to 585 nits.

For another example, the weight ratio of the filler S to the optical layer 1030 may be 1 percent, and the light passing through the optical layer 1030 from the above-described light emitting elements RGB may be 600 to 605 nits.

For another example, the weight ratio of the filler S to the optical layer 1030 may be 5 percent, and the light passing through the optical layer 1030 from the above-described light emitting elements RGB may be 640 to 648 nits. At this time, the color coordinates may be 0.293 (Cx) and 0.323 (Cy).

For another example, the weight ratio of the filler S to the optical layer 1030 may be 10 percent, and the light passing through the optical layer 1030 from the above-described light emitting elements RGB may be 680 to 686 nits. At this time, the color coordinates may be 0.291 (Cx) and 0.325 (Cy).

FIG. 6 shows the luminance of light passing through the optical layer 1030 containing the filler S compared to the luminance of the optical layer 1030 that does not contain the filler S. For example, the luminance of light passing through the optical layer 1030 that contains 500 nanometer fillers S at a weight ratio of 0.5 percent compared to the optical layer 1030 may be the same as the luminance of light passing through the optical layer 1030 that does not contain fillers S by 100 percent.

For another example, the luminance of light passing through the optical layer 1030 that contains 500 nanometer fillers S at a weight ratio of 1 percent compared to the optical layer 1030 may be greater than the luminance of light passing through the optical layer 1030 that does not contain the filler S by 102 to 104 percent.

For another example, the luminance of light passing through the optical layer 1030 that contains 500 nanometer fillers S at a weight ratio of 5 percent compared to the optical layer 1030 may be greater than the luminance of light passing through the optical layer 1030 that does not contain fillers S by 110 to 112 percent.

For another example, the luminance of light passing through the optical layer 1030 that contains 500 nanometer fillers S at a weight ratio of 10 percent compared to the optical layer 1030 may be greater than the luminance of light passing through the optical layer 1030 that does not contain the fillers S by 116 to 118 percent.

When the weight ratio of the 500 nanometer fillers S is greater than 12 percent compared to the optical layer 1030, the fillers S may agglomerate and the luminance of light passing through the optical layer 1030 may decrease. In addition, the distinction between RGB pixels may become unclear and light compensation may become difficult.

Accordingly, the black color expression of the display device may be improved. In addition, it may improve a difference in color that can be caused by differences in the transmittance of the optical layer between red, green, and blue light which are the light provided by light emitting element RGB. That is, as the wavelength of light becomes longer, the amount of light extracted by refraction becomes greater. This means that in a phenomenon in which the display panel may be perceived as a red color on the whole, the color difference can be improved by improving the extraction amount of green and/or blue light.

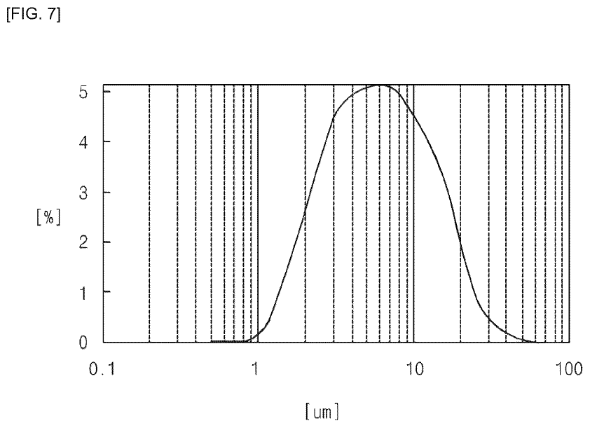

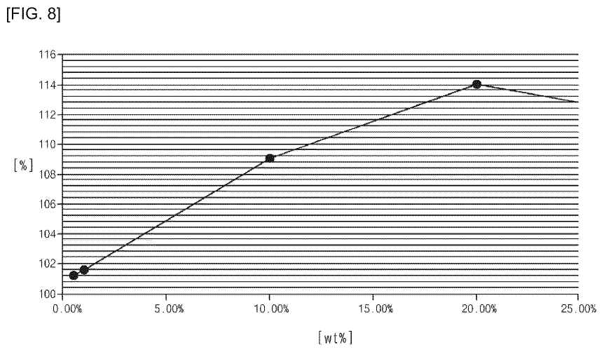

Referring to FIGS. 7 and 8, the filler S may include a plurality of fillers S of different sizes. The sizes of the fillers S may form a normal distribution. The plurality of fillers S may be 5 nanometer fillers. FIG. 7 shows the particle size distribution of fillers S, the horizontal axis may be the size (micrometer, log scale) of the fillers, and the vertical axis may be the quantity distribution (percent).

For example, fillers of 0 to 2 micron meters may have a 21.8 percent distribution, fillers of 2 to 6 micron meters may have a 46.7 percent distribution, fillers of 6 to 16 micron meters may have a 30.2 percent distribution, and fillers of 16 to 24 micron meters may have a distribution of 1.3 percent. As another example, fillers of 2 to 16 micrometers in diameter may have a distribution of 75 to 80 percent.

The fillers S may be contained in the optical layer 1030. For example, the weight ratio of the filler S to the optical layer 1030 may be 0.5 percent, and the light passing through the optical layer 1030 from the above-described light emitting elements RGB may be 587 to 590 nits.

For another example, the weight ratio of the filler S to the optical layer 1030 may be 1 percent, and the light passing through the optical layer 1030 from the above-described light emitting elements RGB may be 591 to 593 nits.

For another example, the weight ratio of the filler S to the optical layer 1030 may be 10 percent, and the light passing through the optical layer 1030 from the above-described light emitting elements RGB may be 633 to 637 nits. At this time, the color coordinates may be 0.301 (Cx) and 0.325 (Cy).

For another example, the weight ratio of the filler S to the optical layer 1030 may be 20 percent, and the light passing through the optical layer 1030 from the above-described light emitting elements RGB may be 665 to 667 nits. At this time, the color coordinates may be 0.296 (Cx) and 0.327 (Cy).

FIG. 8 shows the luminance of light passing through the optical layer 1030 containing the filler S compared to the luminance of the optical layer 1030 that does not contain the filler S. For example, the luminance of light passing through the optical layer 1030 that contains 5 micrometer fillers S at a weight ratio of 0.5 percent compared to the optical layer 1030 may be greater than the luminance of light passing through the optical layer 1030 that does not contain fillers S by 101.2 percent.

For another example, the luminance of light passing through the optical layer 1030 that contains 5 micrometer fillers S at a weight ratio of 1 percent compared to the optical layer 1030 may be greater than the luminance of light passing through the optical layer 1030 that does not contain the filler S by 100 to 102 percent.

For another example, the luminance of light passing through the optical layer 1030 that contains 5 micrometer fillers S at a weight ratio of 10 percent compared to the optical layer 1030 may be greater than the luminance of light passing through the optical layer 1030 that does not contain fillers S by 108 to 110 percent.

For another example, the luminance of light passing through the optical layer 1030 that contains 5 micrometer fillers S at a weight ratio of 20 percent compared to the optical layer 1030 may be greater than the luminance of light passing through the optical layer 1030 that does not contain the fillers S by 113 to 116 percent.

For another example, the uniformity of light passing through the optical layer 1030 that contains 5 micrometer fillers S at a weight ratio of 15 to 23 percent compared to the optical layer 1030 may be improved in luminance and uniformity compared to light passing through the optical layer 1030 that does not contain the fillers S.

When the weight ratio of the 5 micrometer fillers S is greater than 25 percent compared to the optical layer 1030, the fillers S may agglomerate and the luminance of light passing through the optical layer 1030 may decrease. In addition, the distinction between RGB pixels may become unclear and light compensation may become difficult.

Accordingly, the black color expression of the display device may be improved. In addition, it may improve a difference in color that can be caused by differences in the transmittance of the optical layer between red, green, and blue light which are the light provided by light emitting element RGB. That is, as the wavelength of light becomes longer, the amount of light extracted by refraction becomes greater. This means that in a phenomenon in which the display panel may be perceived as a red color on the whole, the color difference can be improved by improving the extraction amount of green and/or blue light.

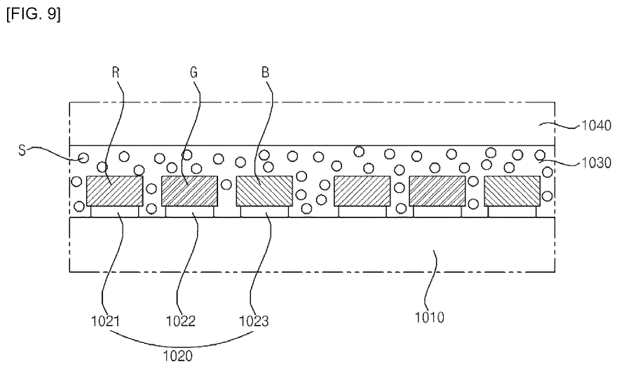

Referring to FIG. 9, the optical layer 1030 may be located on the substrate 1010 on which the light emitting element RGB is mounted. The optical layer 1030 may cover and seal the light emitting element RGB mounted on the substrate 1010. The optical layer 1030 may be coated and cured in a liquid form on the substrate 1010 and the light emitting element RGB. For example, the optical layer 1030 may include silicone. The optical layer 1030 may be transparent.

The filler S may be contained in the optical layer 1030, as described above. For example, the filler S may be a plurality of particles(S). The filler S may be, for example, SiO2. For example, the filler S may be spherical and have a diameter of 500 nanometers to 5 micron meters.

The optical layer 1030 containing the filler S may be aged at about 60 degrees Celsius for about 1 hour. The thickness of the aged optical layer 1030 may be reduced through a lapping process that grinds the surface. The surface processed through the lapping process may be the upper surface of the optical layer 1030. The filler S may be exposed to the upper surface of the optical layer 1030. The filler S exposed to the upper surface of the optical layer 1030 may have a part of its spherical shape cut out, and the cut surface of the filler S may be exposed to the outside.

For example, the thickness of the optical layer 1030 may be about 150 micrometers, and the thickness from the upper surface of the light emitting element RGB to the upper surface of the optical layer 1030 may be about 50 micrometers. The thickness of the light emitting element RGB may be about 80 micrometers, and the thickness of the electrode pad 1020 may be about 20 micrometers.

The light provided from the light emitting element RGB may be refracted or scattered in the filler S. The light scattered in the filler S may leak out of the optical layer 1030. After cured, the optical layer 1030 may be transparent. For example, the cured optical layer 1030 containing silicon may have a refractive index of 1.5 to 1.6. Accordingly, the light may be totally reflected inside the optical layer 1030. The filler S may refract or scatter light that is totally reflected inside the optical layer 1030.

An optical film 1040 may be located on the optical layer 1030. The optical film 1040 may be contacted or adhered on the optical layer 1030. For example, the optical film 1040 may include a black material and may be laminated on the optical layer 1030. For example, the black material may be particles less than 10 nanometres. For example, the optical film 1040 may have an optical transmittance of 40 percent.

Accordingly, the black color expression of the display device may be improved. In addition, it may improve a difference in color that can be caused by differences in the transmittance of the optical layer between red, green, and blue light which are the light provided by light emitting element RGB. That is, as the wavelength of light becomes longer, the amount of light extracted by refraction becomes greater. This means that in a phenomenon in which the display panel may be perceived as a red color on the whole, the color difference can be improved by improving the extraction amount of green and/or blue light.

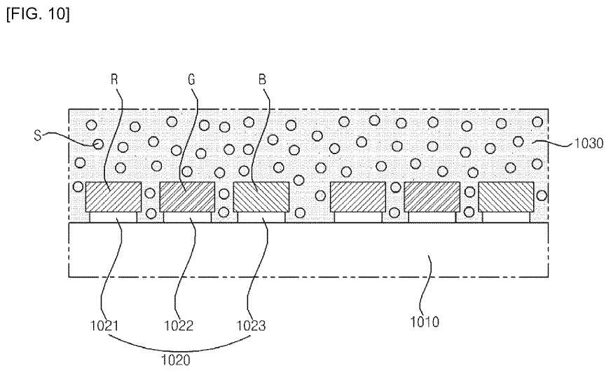

Referring to FIG. 10, the optical layer 1030 may be located on the substrate 1010 on which the light emitting element RGB is mounted. The optical layer 1030 may cover and seal the light emitting element RGB mounted on the substrate 1010. The optical layer 1030 may be coated in a liquid form on the substrate 1010 and the light emitting element RGB and cured. For example, the optical layer 1030 may include silicone. The optical layer 1030 may be transparent.

The filler S may be, as described above, contained in the optical layer 1030. For example, the filler S may be a plurality of particles S. The filler S may be, for example, SiO2. For example, the filler S may be spherical and have a diameter of 500 nanometers to 5 micron meters.

The optical layer 1030 may include a black material. The black material may be a particle of 10 nanometers, and may have a weight ratio of 10 percent or less compared to the optical layer 1030.

The optical layer 1030 containing the filler S and the black material may be aged at about 60 degrees Celsius for about 1 hour. The thickness of the aged optical layer 1030 may be reduced through a lapping process that grinds the surface. The surface processed through the lapping process may be the upper surface of the optical layer 1030. The filler S may be exposed to the upper surface of the optical layer 1030. The filler S exposed to the upper surface of the optical layer 1030 may have a part of its spherical shape cut out, and the cut surface of the filler S may be exposed to the outside.

For example, the thickness of the optical layer 1030 may be about 150 micrometers, and the thickness from the upper surface of the light emitting element RGB to the upper surface of the optical layer 1030 may be about 50 micrometers. The thickness of the light emitting element RGB may be about 80 micrometers, and the thickness of the electrode pad 1020 may be about 20 micrometers.

The light provided from the light emitting element RGB may be refracted or scattered in the filler S. The light scattered in the filler S may leak out of the optical layer 1030. After cured, the optical layer 1030 containing the filler S and the black material may be transparent.

Accordingly, the black color expression of the display device may be improved. In addition, it may improve a difference in color that can be caused by differences in the transmittance of the optical layer between red, green, and blue light which are the light provided by light emitting element RGB. That is, as the wavelength of light becomes longer, the amount of light extracted by refraction becomes greater. This means that in a phenomenon in which the display panel may be perceived as a red color on the whole, the color difference can be improved by improving the extraction amount of green and/or blue light.

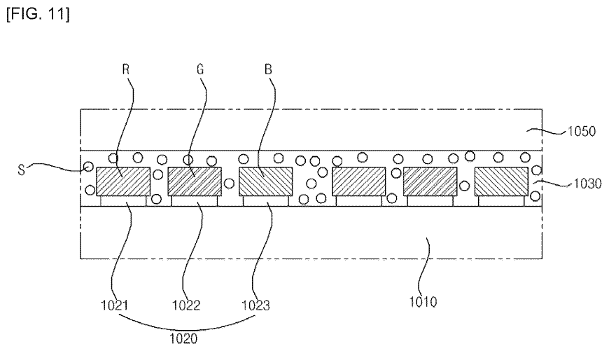

Referring to FIG. 11, a first optical layer 1030 may be located on the substrate 1010 on which the light emitting element RGB is mounted. The first optical layer 1030 may cover and seal the light emitting element RGB mounted on the substrate 1010. The first optical layer 1030 may be coated in a liquid form on the substrate 1010 and the light emitting element RGB and cured. For example, the first optical layer 1030 may include silicone. The first optical layer 1030 may be transparent.

The filler S, as described above, may be contained in the first optical layer 1030. For example, the filler S may be a plurality of particles S. The filler S may be, for example, SiO2. For example, the filler S may be spherical and have a diameter of 500 nanometers to 5 micron meters.

The optical layer 1030 including the filler S may be aged at about 60 degrees Celsius for about 1 hour. The thickness of the aged optical layer 1030 may be reduced through a lapping process that grinds the surface. The surface processed through the lapping process may be the upper surface of the optical layer 1030. The filler S may be exposed to the upper surface of the optical layer 1030. The filler S exposed to the upper surface of the optical layer 1030 may have a part of its spherical shape cut out, and the cut surface of the filler S may be exposed to the outside.

For example, the thickness of the optical layer 1030 may be about 150 micrometers, and the thickness from the upper surface of the light emitting element RGB to the upper surface of the optical layer 1030 may be about 50 micrometers. The thickness of the light emitting element RGB may be about 80 micrometers, and the thickness of the electrode pad 1020 may be about 20 micrometers.

The light provided from the light emitting element RGB may be refracted or scattered in the filler S. The light scattered in the filler S may leak out of the first optical layer 1030. After cured, the first optical layer 1030 may be transparent. For example, the cured first optical layer 1030 containing silicon may have a refractive index of 1.5 to 1.6. For another example, the cured first optical layer 1030 containing silicon may have a refractive index of 1.41.

A second optical layer 1050 may be located on the first optical layer 1030. The second optical layer 1050 may be coated and cured in a liquid form on the first optical layer 1030. For example, the second optical layer 1050 may contain silicone. The second optical layer 1050 may be transparent. For example, the cured second optical layer 1050 containing silicon may have a refractive index of 1.4 to 1.5. For another example, the cured second optical layer 1050 containing silicon may have a refractive index of 1.41.

Accordingly, the light extraction efficiency of the light that is provided from the light emitting element RGB and passes through the first optical layer 1030 and the second optical layer 1050 may be improved.

Referring to FIGS. 1 to 11, a display device according to an aspect of the present disclosure may include: a display panel; and a module cover to which the display panel is coupled, wherein the display panel may include: a flat substrate; a plurality of electrode pads formed on the substrate; a plurality of light emitting elements mounted on each of the plurality of electrode pads; an optical layer covering the plurality of light emitting elements, and formed on the substrate; and a plurality of fillers formed of a spherical particle, and distributed inside the optical layer, wherein 75 to 80 percent of the plurality of fillers may have a diameter of 2 to 16 micrometers, and a weight ratio of the plurality of fillers compared to the optical layer may be 15 to 23 percent.

According to another aspect of the present disclosure, the optical layer may have transparency, and the plurality of fillers may have a weight ratio of 20 percent compared to the optical layer.

According to another aspect of the present disclosure, the optical layer may further include a black material which is particles of 10 nanometers or less, and may have a weight ratio of 10 percent or less compared to the optical layer, so that the optical layer has translucency.

According to another aspect of the present disclosure, the display device may further include an optical film which is located on the optical layer, and having an optical transmittance of 35 to 45 percent.

According to another aspect of the present disclosure, the optical layer may be a first optical layer having a first refractive index, and the display device may further include a second optical layer located on the first optical layer and having a second refractive index less than the first refractive index.

According to another aspect of the present disclosure, the first refractive index may be 1.5 to 1.6, and the second refractive index is 1.4 to 1.5.

According to another aspect of the present disclosure, the first refractive index may be 1.53 and the second refractive index is 1.41.

According to another aspect of the present disclosure, at least part of the plurality of fillers may form a part of an upper surface of the optical layer.

According to another aspect of the present disclosure, a thickness of the optical layer may be 140 to 160 micrometers, and a distance between an upper surface of the light emitting element and the upper surface of the optical layer may be 40 to 60 micrometers.

According to another aspect of the present disclosure, at least part of the plurality of fillers forming a part of the upper surface of the optical layer may have a cut-out section of a spherical shape.

Certain embodiments or other embodiments of the disclosure described above are not mutually exclusive or distinct from each other. Any or all elements of the embodiments of the disclosure described above may be combined or combined with each other in configuration or function.

For example, a configuration “A” described in one embodiment of the disclosure and the drawings and a configuration “B” described in another embodiment of the disclosure and the drawings may be combined with each other. Namely, although the combination between the configurations is not directly described, the combination is possible except in the case where it is described that the combination is impossible.

Although embodiments have been described with reference to a number of illustrative embodiments thereof, it should be understood that numerous other modifications and embodiments can be devised by those skilled in the art that will fall within the scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

1. A display device comprising:
a display panel; and
a module cover to which the display panel is coupled,
wherein the display panel comprises:
a flat substrate;
a plurality of electrode pads formed on the substrate;
a plurality of light emitting elements mounted on each of the plurality of electrode pads;
an optical layer covering the plurality of light emitting elements, and formed on the substrate; and
a plurality of fillers formed of a spherical particle, and distributed inside the optical layer,
wherein 75 to 80 percent of the plurality of fillers have a diameter of 2 to 16 micrometers, and a weight ratio of the plurality of fillers compared to the optical layer is 15 to 23 percent.

2. The display device of claim 1, wherein the optical layer has transparency, and the plurality of fillers have a weight ratio of 20 percent compared to the optical layer.

3. The display device of claim 2, wherein the optical layer further comprises a black material which is particles of 10 nanometers or less, and has a weight ratio of 10 percent or less compared to the optical layer, so that the optical layer has translucency.

4. The display device of claim 2, further comprises an optical film located on the optical layer, and having an optical transmittance of 35 to 45 percent.

5. The display device of claim 2, wherein the optical layer is a first optical layer having a first refractive index, and
further comprising a second optical layer located on the first optical layer and having a second refractive index less than the first refractive index.

6. The display device of claim 5, wherein the first refractive index is 1.5 to 1.6, and the second refractive index is 1.4 to 1.5.

7. The display device of claim 6, wherein the first refractive index is 1.53 and the second refractive index is 1.41.

8. The display device of claim 2, wherein at least part of the plurality of fillers form a part of an upper surface of the optical layer.

9. The display device of claim 8, wherein a thickness of the optical layer is 140 to 160 micrometers,
wherein a distance between an upper surface of the light emitting element and the upper surface of the optical layer is 40 to 60 micrometers.

10. The display device of claim 9, wherein at least part of the plurality of fillers forming a part of the upper surface of the optical layer have a cut-out section of a spherical shape.
